(19) United States
(12) Patent Application Publication
(10) Pub. No.: US 2011/0053336 A1
(43) Pub. Date: Mar. 3, 2011

(54) METHOD FOR SELECTIVE DEPOSITION OF DIELECTRIC LAYERS ON SEMICONDUCTOR STRUCTURES

(75) Inventors: Kiuchul Hwang, Amherst, NH (US); David W. Bennett, Templeton, MA (US); Huy Q. Nguyen, Dorchester, MA (US)

(73) Assignee: Raytheon Company, Waltham, MA (US)

(21) Appl. No.: 12/553,261

(22) Filed: Sep. 3, 2009

(51) Int. Cl. H01L 21/02

(52) U.S. Cl. 438/393; 257/E21.008

(57) ABSTRACT

A method for forming a capacitor and a transistor device on different surface portions of a semiconductor structure includes forming a passivation dielectric layer for the device; forming a bottom electrode for the capacitor; forming a removable layer extending over the bottom electrode and over the passivation dielectric layer with a window therein, such window exposing said bottom electrode; depositing a capacitor dielectric layer of the same or different material as the passivation dielectric layer over the removable layer with first portions passing through the window onto the exposed bottom electrode and second portions being over the removable layer, the thickness of the deposited layer being different from the thickness of the passivation layer; removing the removable layer with the second portions thereon while leaving said first portions on the bottom electrode; and forming a top electrode for the capacitor on the second portions remaining on the bottom electrode.

### TECHNICAL FIELD

This disclosure relates generally to methods for forming dielectric layers on semiconductors structures and more particularly to methods for forming a capacitor and a transistor device on different surface portions of a semiconductor structure.

### BACKGROUND

As is known in the art, in the many present FET/HEMT/HBT transistor based MMIC fabrication processes, two layers of dielectrics such as SiₓN_{y}, SiₓO_{y}, AlₓO_{y} are deposited over the active region between the source and drain contacts of the FET/HEMT devices or between the emitter, base, and collector contacts of the HBT devices: (1) a passivation dielectric layer; and (2) a capacitor dielectric layer. The addition of latter layer on the active transistor adds parasitic capacitance to the active region (e.g. source-gate, gate-drain, source-drain, emitter-base, base-collector) thereby unnecessarily degrading rf gain performance of the device significantly; e.g., by as much as 2 dB depending on the operation frequency for many transistors.

The impact of RF loading that the capacitor dielectric brings to the transistors can be observed from G_{MAX} measurements. G_{MAX} may be lowered by up to 2.0-2.5 dB due to the addition of 200-nm capacitor SiN. Since the function of the capacitor dielectric does not bring any benefit to the transistors, the finished device will inherently incur a 2-3 dB gain hit. This clearly necessitates a transistor process that either removes the capacitor dielectric in the transistor or if warranted for environmental protection and/or reliability, replaces it with an alternate dielectric film with a significantly lower dielectric constant. Depositing a significantly thinner capacitor dielectric say for example 100-nm or less would greatly mitigate the rf loading to the transistor but such thin films may bring another problem by lowering capacitor breakdown voltage and high rate of capacitor failures due to pinholes.

### SUMMARY

In accordance with the present disclosure, a method is provided for forming a capacitor and a transistor device on different surface portions of a semiconductor structure. The method includes: forming a passivation layer for the device; forming a bottom electrode for the capacitor; forming a removable layer extending over the bottom electrode and over the passivation layer with a window therein, such window exposing said bottom electrode; depositing a capacitor dielectric layer over the removable layer with first portions passing through the window onto the exposed bottom electrode and second portions being deposited over the photoresist layer, the thickness of the deposited layer being different from the thickness of the passivation layer; removing the removable layer with the second portions of the deposited layer thereon while leaving said first portions of the deposited layer on the bottom electrode; and forming a top electrode for the capacitor on the first portions of the dielectric layer remaining on the bottom electrode.

In one embodiment, a method for forming a capacitor and a transistor device on different surface portions of a semiconductor structure includes: forming a first dielectric layer passivation layer for the transistor device between device contacts; forming a bottom electrode for the capacitor over a second different surface portion of the semiconductor structure; forming a removable layer extending over the bottom electrode and over the passivation layer, such removable layer being formed with a window therein, such window being disposed over the bottom electrode to expose said bottom electrode, such window being narrower at an upper portion of the window than at a lower portion of the window; depositing a second dielectric layer of the same material as the first dielectric layer over the removable layer with portions of the material in the deposited second dielectric layer being deposited on the removable layer and other portions of the deposited second dielectric layer passing through the window onto the exposed bottom electrode and being spaced from the portions of the second dielectric layer deposited on the removable layer, the thickness of the deposited second dielectric layer different from the thickness of the first dielectric layer; removing the removable layer together with the portions of the deposited on the removable layer while leaving said other portions of the deposited second dielectric layer on the bottom electrode; and forming a top electrode for the capacitor on the portions of the second dielectric layer remaining on the bottom electrode.

In one embodiment, the dielectric material is silicon nitride, silicon oxide, or aluminum oxide.

In one embodiment, the window is dove-shaped.

In one embodiment, the removable layer is a photoresist layer.

In one embodiment, the photoresist layer is an image reversal photoresist layer.

In one embodiment, the passivation dielectric layer has a thickness different from the capacitor dielectric layer.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIGS. 1-5 show a semiconductor structure having a capacitor and a FET/HEMT transistor device on different surface portions of a semiconductor structure at various stages in the fabrication thereof in accordance with the disclosure; and

FIG. 6-10 shows a semiconductor structure having a capacitor and a bipolar transistor device on different surface portions of a semiconductor structure at various stages in the fabrication thereof in accordance with another embodiment of the disclosure

Like reference symbols in the various drawings indicate like elements.

### DETAILED DESCRIPTION

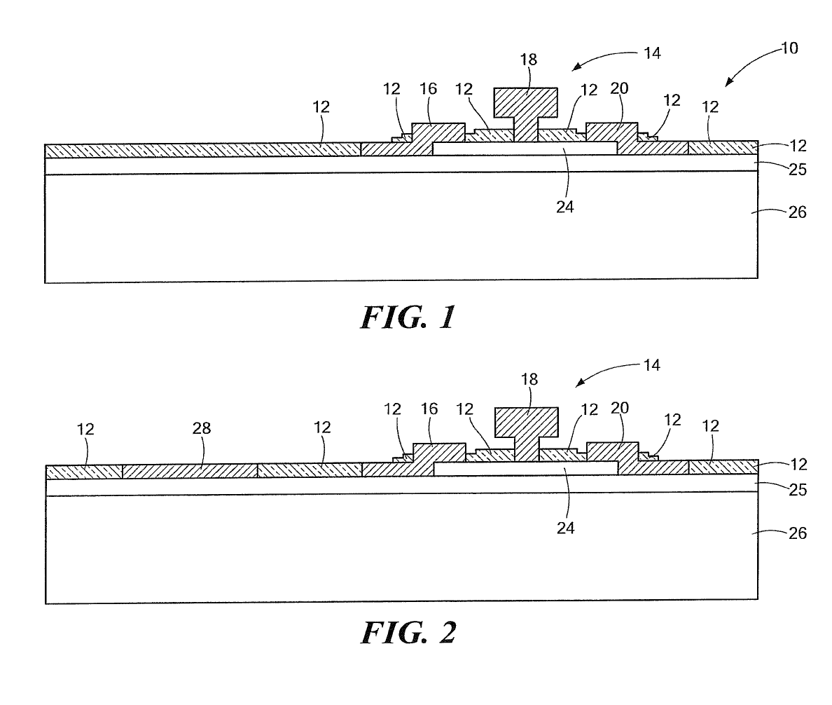

Referring now to FIG. 1, a semiconductor structure 10 is shown having a dielectric passivation layer 12 formed for a transistor device 14 between source and gate contacts 16, 18, respectively, and between gate and drain contacts 18, 20, respectively, of the device 14. Here, the transistor device 14 is a FET formed with an active FET region 24 on a buffer layer 25 formed on a semiconductor substrate 26.

Next, referring to FIG. 2, a bottom electrode 28 for a capacitor to be formed on a different region of the structure from the region having the transistor device 14 is formed using conventional lithographic-etching-metal deposition.

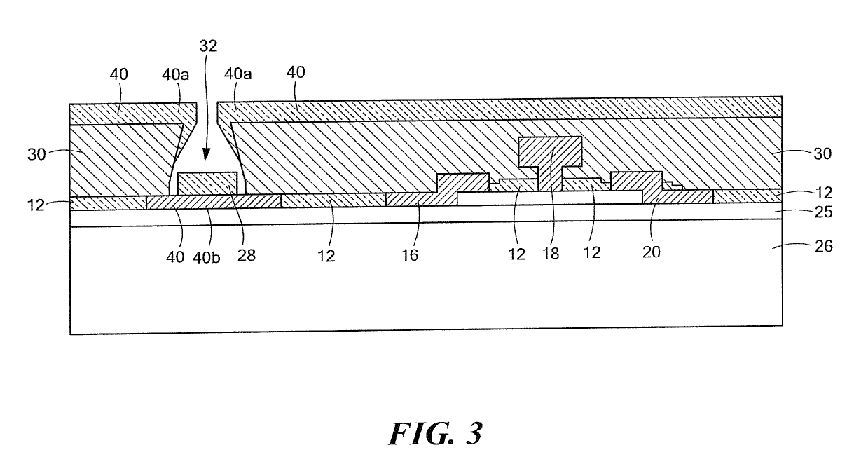

Next, referring to FIG. 3, a removable layer 30 is deposited in any conventional manner over the surface of the structure, such removable layer extending over the bottom electrode 28 and over the passivation layer 12, as shown. A conventional adhesion promoter layer, not shown, may be deposited over the structure prior to the deposition of the photoresist layer. Here, the removable layer is, for example, an image reversal type photoresist layer 30. The removable layer 30 is processed in a conventional manner to have a window 32 formed therein. Here the window 32 is formed over the bottom electrode 28 to expose said bottom electrode 28. It is noted that the window 32 is dove shaped having an upper portion narrower than at its lower portion, as shown in FIG. 3.

Next, a dielectric layer 40 of the same or different material as the passivation dielectric layer 12 is deposited over the removable layer 30 with portions 40a of the material of layer 40 being deposited on the removable layer 30 and other portions 40b of the deposited dielectric layer 40 passing through the window 32 onto the exposed bottom electrode 28 and being spaced from the portions 40a of the dielectric layer 40 deposited on the removable layer 30, as shown in FIG. 3. Here the thickness of the deposited dielectric layer 40 is different from the thickness of the passivation dielectric layer 12.

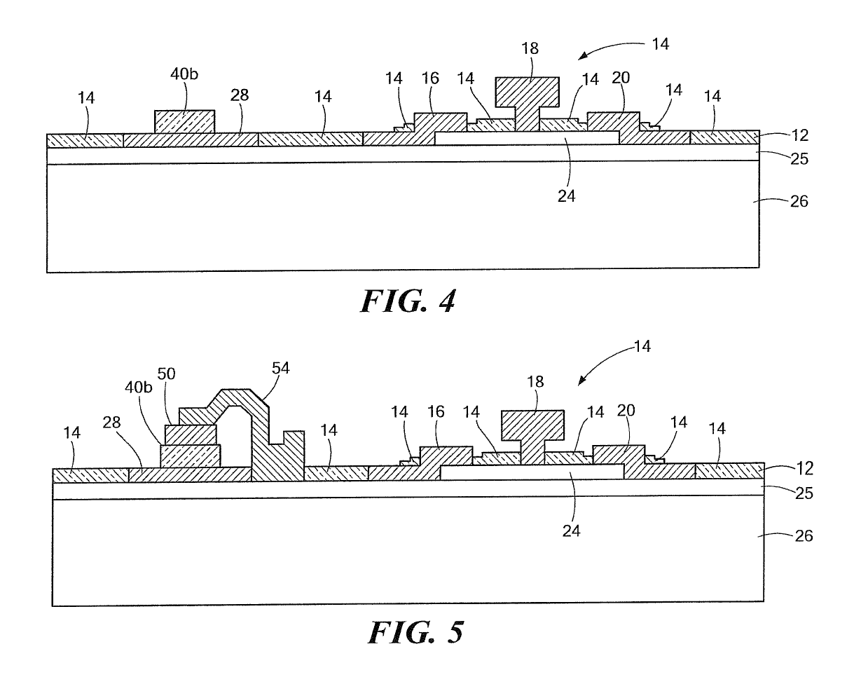

Next, as shown in FIG. 4, the removable layer 30 (FIG. 3) (together with any adhesion promoter layer), is lifted off together with the portions 40a of the deposited layer 40 on the removable layer 30 while leaving the portions 40b of the deposited dielectric layer 40 on the bottom electrode 28, as shown in FIG. 4.

Next, as shown in FIG. 5, a top electrode 50 for the capacitor 52 is formed in any conventional manner on the portions 40b of the dielectric layer 40 remaining on the bottom electrode 28 to form the structure shown in FIG. 5. Finally, an electrical interconnect 54 is formed in a conventional manner to electrically interconnect the interconnect 54 to the source electrode 16 of the transistor device 14.

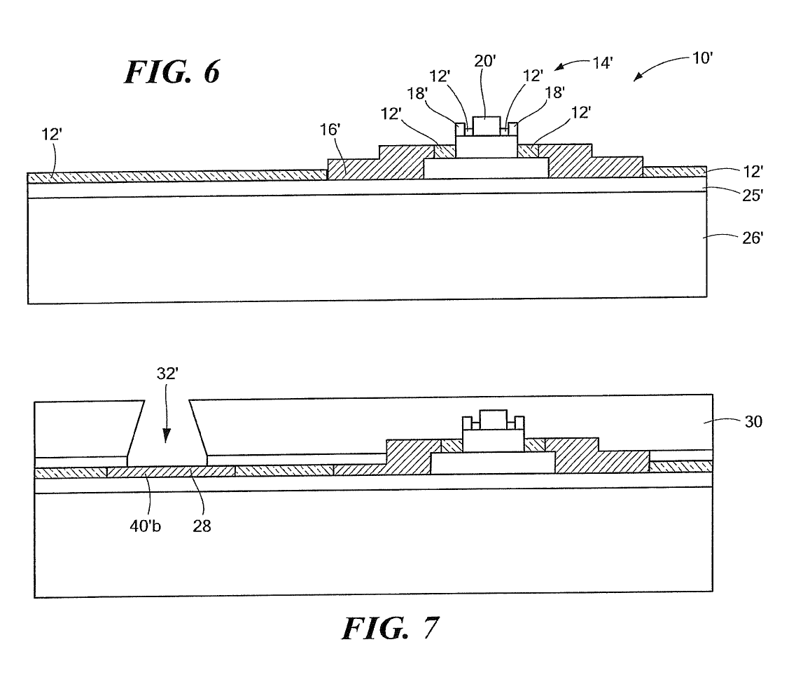

Referring now to FIGS. 6-10, the method described above is applied to a bipolar transistor. Thus, referring to FIG. 6, a semiconductor structure 10′ is shown having a dielectric passivation layer 12′ formed for a bipolar transistor device 14′ having a collector contact 16, a base contact 18′ and an emitter contact 20′.

Next, referring to FIG. 7, a removable layer 30′ is deposited in any conventional manner extending over a bottom electrode 28 and over the passivation layer 12′, as shown. A conventional adhesion promoter layer, not shown, may be deposited over the structure prior to the deposition of the photoresist layer. Here, the removable layer is, for example, an image reversal type photoresist layer 30. The removable layer 30′ is processed in a conventional manner to have a window 32′ formed therein. Here the window 32′ is formed over the bottom electrode 28 to expose said bottom electrode 28. It is noted that the window 32′ is dove shaped having an upper portion narrower than at its lower portion, as shown in FIG. 7.

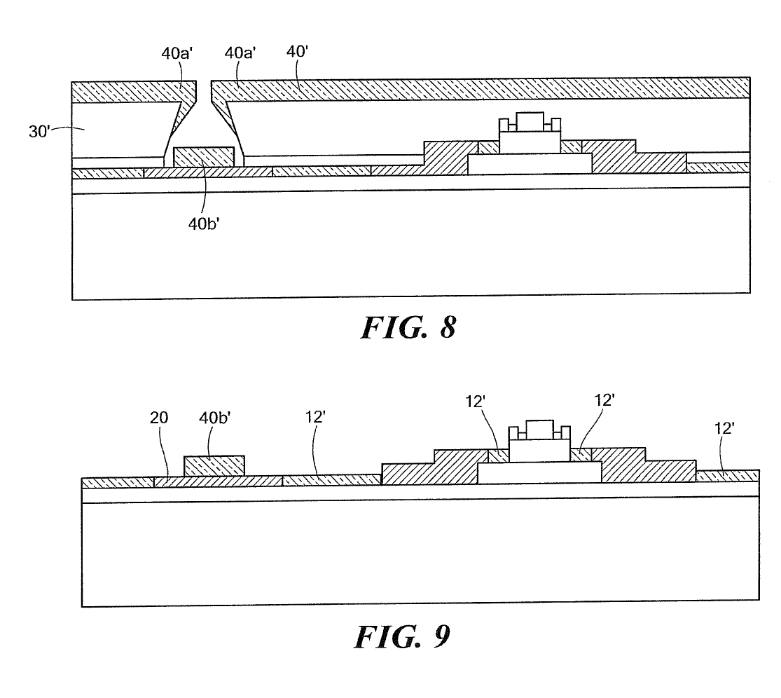

Next, a dielectric layer 40′ of the same or different material as the passivation dielectric layer′ is deposited over the removable layer 30′ with portions 40′a of the material of layer 40′ being deposited on the removable layer 30′ and other portions 40′b of the deposited dielectric layer 40′ passing through the window 32′ onto the exposed bottom electrode 28 and being spaced from the portions 40′a of the dielectric layer 40′ deposited on the removable layer 30′, as shown in FIG. 8. Here the thickness of the deposited dielectric layer 40′ is different from the thickness of the passivation dielectric layer 12′.

Next, as shown in FIG. 9, the removable layer 30′ (FIG. 8) (together with any adhesion promoter layer), is lifted off together with the portions 40′a of the deposited layer 40′ on the removable layer 30′ while leaving the portions 40′b of the deposited dielectric layer 40′ on the bottom electrode 28.

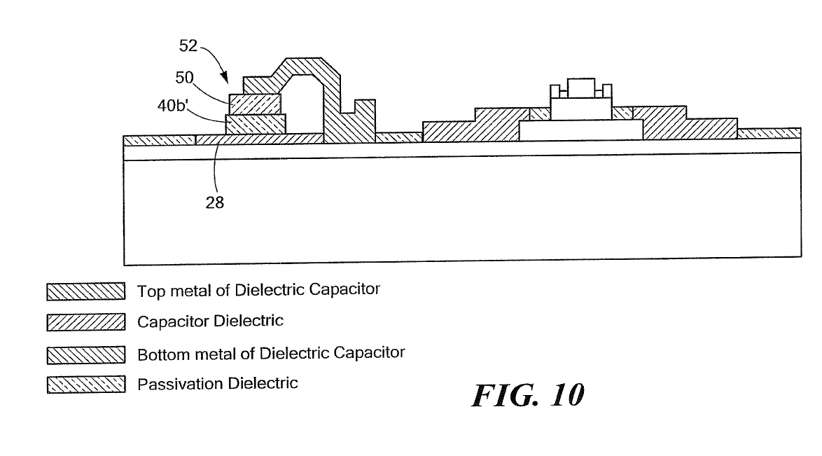

Next, as shown in FIG. 10, a top electrode 50 for the capacitor 52 is formed in any conventional manner on the portions 40′b of the dielectric layer 40 remaining on the bottom electrode 28 to form the structure shown in FIG. 10.

A number of embodiments of the disclosure have been described. Nevertheless, it will be understood that various modifications may be made without departing from the spirit and scope of the disclosure. For example, the passivation layer and capacitor dielectric layers may have other thicknesses, for example, if the active transistor area has 2000A passivation, is then capacitor thickness could be 200A, 300A, 500A, 1000A or 4000A, vice versa. Accordingly, other embodiments are within the scope of the following claims.

What is claimed is:

1. A method for forming a capacitor and a transistor device on different surface portions of a semiconductor structure, comprising:
forming a passivation dielectric layer for the device;
forming a bottom electrode for the capacitor;
forming a removable layer extending over the bottom electrode and over the the passivation dielectric layer with a window therein, such window exposing said bottom electrode;
depositing a capacitor dielectric layer of the same or different material as the passivation dielectric layer over the removable layer with first portions passing through the window onto the exposed bottom electrode and with second portions being over the removable layer, the thickness of the deposited capacitor dielectric layer being different from the thickness of the passivation dielectric layer;
removing the removable layer with the second portions thereover while leaving said first portions on the bottom electrode; and
forming a top electrode for the capacitor on the first portions remaining on the bottom electrode.

2. The method recited in claim 1 wherein the dielectric material of the passivation dielectric layer and the capacitor dielectric layer is silicon nitride, silicon oxide or aluminum oxide.

3. The method recited in claim 1 wherein the window is dove-shaped.

4. The method recited in claim 1 wherein the removable layer is a photoresist layer.

5. The method recited in claim 1 wherein the deposited capacitor dielectric layer is different from the material of the passivation dielectric layer.

6. The method recited in claim 1 wherein the deposited capacitor dielectric layer is the same material as the passivation dielectric layer.

7. A method for forming a capacitor and a transistor device on different surface portions of a semiconductor structure, comprising:
forming a first dielectric layer as a passivation layer for the transistor device between contacts of the device;
forming a bottom electrode for the capacitor over a second different surface portion of the semiconductor structure;
forming a removable layer extending over the bottom electrode and over the the passivation dielectric layer, such removable layer being formed with a window therein, such window being disposed over the bottom electrode to expose said bottom electrode, such window being narrower at an upper portion of the window than at a lower portion of the window;
depositing a second dielectric layer over the removable layer with first portions of the second dielectric being deposited on the removable layer and second portions of the deposited second dielectric layer passing through the window onto the exposed bottom electrode and being spaced from the portions of the second dielectric layer deposited on the removable layer, the thickness of the deposited second dielectric layer being different from the thickness of the first dielectric layer; and
removing the removable layer together with the first portions thereon while leaving said second portions on the bottom electrode; and
forming a top electrode for the capacitor on the second portions of the second dielectric layer remaining on the bottom electrode.

8. The method recited in claim 7 wherein the dielectric material of the first dielectric layer and the second dielectric layer is silicon nitride, silicon oxide, or aluminum oxide.

9. The method recited in claim 7 wherein the window is dove-shaped.

10. The method recited in claim 7 wherein the removable layer is a photoresist layer.

11. The method recited in claim 7 wherein the deposited capacitor dielectric layer is different from the material of the passivation dielectric layer.

12. The method recited in claim 7 wherein the first dielectric layer and the second dielectric layer are the same material.

13. The method recited in claim 7 wherein the passivation layer has a different thickness from the second dielectric layer.

14. The method recited in claim 7 wherein the first dielectric layer and the second dielectric layer are the same thickness.
